(19) United States
(12) Patent Application Publication
(10) Pub. No.: US 2025/0087948 A1
(43) Pub. Date: Mar. 13, 2025

(54) CONNECTOR-ATTACHED CABLE

(71) Applicant: SUMITOMO ELECTRIC INDUSTRIES, LTD., Osaka (JP)

(72) Inventors: Naoshige YOKOTA, Tochigi (JP); Takami SAGISAKA, Tochigi (JP); Nobuyuki YAMAZAKI, Tochigi (JP); Wataru SAKURAI, Tochigi (JP)

(73) Assignee: SUMITOMO ELECTRIC INDUSTRIES, LTD., Osaka (JP)

(21) Appl. No.: 18/828,741

(22) Filed: Sep. 9, 2024

(30) Foreign Application Priority Data
Sep. 11, 2023 (JP) 2023-147053

(51) Int. Cl. H01R 13/66; H01R 24/60

(52) U.S. Cl. CPC H01R 13/6658; H01R 24/60

(57) ABSTRACT

A connector-attached cable includes a cable including a plurality of electronic wires; and a connector connected to the cable. The connector includes a circuit board, each of the electronic wires includes a conductor and an insulating layer covering the conductor. The plurality of electronic wires is connected to the circuit board. The plurality of conductors is connected to a first surface and a second surface of the circuit board. An overlapping width between an electronic wire pair in a first group connected to the first surface and an electronic wire pair in a second group connected to the second surface is smaller than a diameter of the electronic wire. When a distance between center lines of two of the electronic wires is set as S, and a diameter of the insulating layer of the electronic wire is set as d, a relationship of S≥0.35d is satisfied.

### TECHNICAL FIELD

The present disclosure relates to a connector-attached cable. This application claims priority based on Japanese Patent Application No. 2023-147053 filed on Sep. 11, 2023, and the entire contents of which are incorporated herein by reference.

### BACKGROUND ART

WO2021/161570 discloses a connector-attached cable that connects a pair of coaxial wires to front and back of a circuit board, respectively.

### SUMMARY

A connector-attached cable according to an aspect of the present disclosure includes:
a cable including a plurality of electronic wires; and
a connector connected to the cable,
the connector includes a circuit board,
each of the electronic wires includes a conductor and an insulating layer covering the conductor,
at least a part of the plurality of electronic wires is connected to the circuit board with two adjacent electronic wires as a pair,
a part of the plurality of conductors is connected to a first surface of the circuit board, and the other part of the plurality of conductors is connected to a second surface on a back side of the first surface,
in a projection view of the electronic wires seen from a direction orthogonal to the first surface or the second surface, an overlapping width between an electronic wire pair in a first group connected to the first surface and an electronic wire pair in a second group connected to the second surface among electronic wire pairs which are connected to different surfaces and closest to each other in the projection view is smaller than a diameter of the electronic wire, and
when a distance between center lines of two of the electronic wires which are connected to different surfaces and overlap each other in the projection view is set as S, and a diameter of the insulating layer of the electronic wire is set as d, a relationship of the following Formula (1) is satisfied,

$$S \geq 0.35 d . \qquad ( 1 )$$

### BRIEF DESCRIPTION OF DRAWINGS

FIG. 1 is a schematic perspective view showing an example of a connector-attached cable according to the present disclosure.

FIG. 2 is an enlarged view of a front end portion of a cable shown in FIG. 1.

FIG. 3 is a schematic perspective view showing an example of a connection form between a circuit board and electronic wires according to the present disclosure.

FIG. 4 is a projection view of the electronic wires and the circuit board seen from a direction orthogonal to a first surface of the circuit board.

FIG. 5A is a cross-sectional view of the electronic wires and the circuit board orthogonal to an axial direction, showing a connection form of the connector-attached cable according to an embodiment.

FIG. 5B is a cross-sectional view of the electronic wires and the circuit board orthogonal to the axial direction, showing another example of the connection form of the connector-attached cable according to the present disclosure.

FIG. 5C is a cross-sectional view of the electronic wires and the circuit board orthogonal to the axial direction, showing another example of the connection form of the connector-attached cable according to the present disclosure.

### DESCRIPTION OF EMBODIMENTS

In the connector-attached cable described in WO2021/161570, it is required to process electronic wires a plurality of times when grounding the electronic wires.

An object of the present disclosure is to provide a connector-attached cable capable of simplifying a step of connecting electronic wires.

According to the above, in the connector-attached cable, a step of connecting the electronic wires to the circuit board is simplified.

### Description of Embodiments of Present Disclosure

First, an embodiment of the present disclosure will be listed and described.

(1) A connector-attached cable according to an aspect of the present disclosure includes: a cable including a plurality of electronic wires; and a connector connected to the cable, the connector includes a circuit board, each of the electronic wires includes a conductor and an insulating layer covering the conductor, at least a part of the plurality of electronic wires is connected to the circuit board with two adjacent electronic wires as a pair, a part of the plurality of conductors is connected to a first surface of the circuit board, and the other part of the plurality of conductors is connected to a second surface on a back side of the first surface, in a projection view of the electronic wires seen from a direction orthogonal to the first surface or the second surface, an overlapping width between an electronic wire pair in a first group connected to the first surface and an electronic wire pair in a second group connected to the second surface among electronic wire pairs which are connected to different surfaces and closest to each other in the projection view is smaller than a diameter of the electronic wire, and when a distance between center lines of two of the electronic wires which are connected to different surfaces and overlap each other in the projection view is set as S, and a diameter of the insulating layer of the electronic wire is set as d, a relationship of the following Formula (1) is satisfied,

$$S \geq 0.35 d . \qquad ( 1 )$$

According to the configuration, in a projection view of the connector-attached cable seen from a direction orthogonal to the surface of the circuit board, a portion where the electronic wires overlap each other can be reduced. When a laser is irradiated from an upper part (or a lower part) of a parallel surface of the electronic wires and an irradiation point is moved in an arrangement direction of the electronic wires to burn off the insulating layers of the electronic wires, the electronic wires attached to the front surface of the circuit board and the electronic wires attached to the back surface of the circuit board can be irradiated with the laser by one operation, and the insulating layers of the electronic wires can be cleaved. Accordingly, a preliminary processing step before the electronic wires are connected to the circuit board can be simplified.

(2) In the above (1), the electronic wire may be a coaxial wire including the conductor, an inner insulating layer, an outer conductor covering the inner insulating layer, and the insulating layer covering the outer conductor.

According to the configuration, when the coaxial wire which requires a plurality of times of processing before being connected to the circuit board, the preliminary processing step can be simplified particularly.

(3) In the above (1) or (2), in the projection view, the diameter d of the insulating layer and the distance S may satisfy a relationship of the following Formula (2),

$$S \geq 0.85 d . \qquad ( 2 )$$

By arranging the electronic wires to satisfy the above relational formula, a connector-attached cable capable of simplifying a step of connecting the electronic wires to the circuit board can be provided.

(4) In the anyone of (1) to (3), the electronic wires may be connected to each of the first surface and the second surface in even pairs.

### Details of Embodiment of Present Disclosure

A specific example of a connector-attached cable according to an embodiment of the present disclosure will be described below with reference to the drawings. The present disclosure is not limited to these exemplifications, but is indicated by the scope of claims, and is intended to include all changes within a scope and meaning equivalent to the scope of claims.

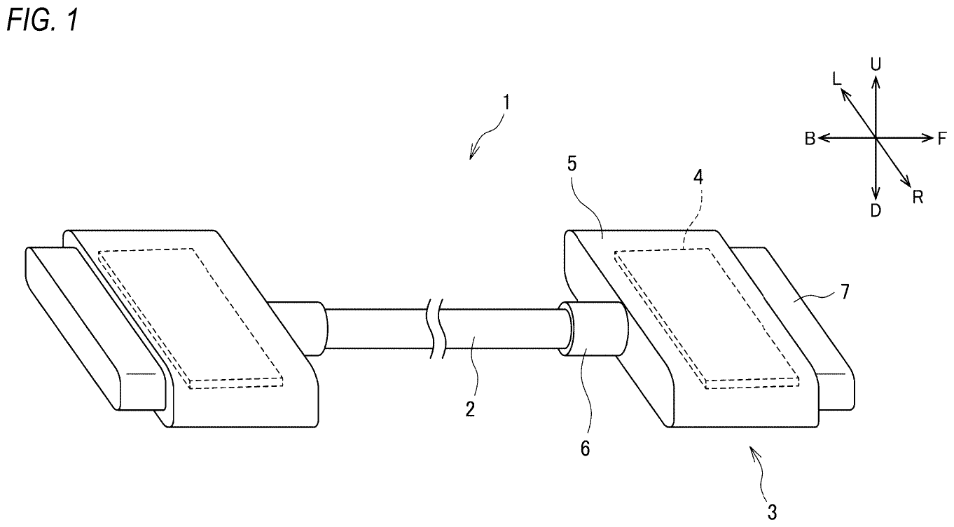

It should be noted that U, D, F, B, R, and L shown in FIG. 1 and the like indicate directions of a connector-attached cable 1, and U indicates an upper direction, D indicates a lower direction, F indicates a front direction, B indicates a rear direction, R indicates a right direction, and L indicates a left direction.

FIG. 1 is a schematic perspective view showing an example of the connector-attached cable 1 according to the present disclosure. The connector-attached cable 1 according to the present embodiment can be used, for example, for connecting electronic devices (not shown) to each other, and a connector 3 is provided on an end portion of a cable 2. As shown in FIG. 1, the connector-attached cable 1 includes the cable 2 and the connector 3.

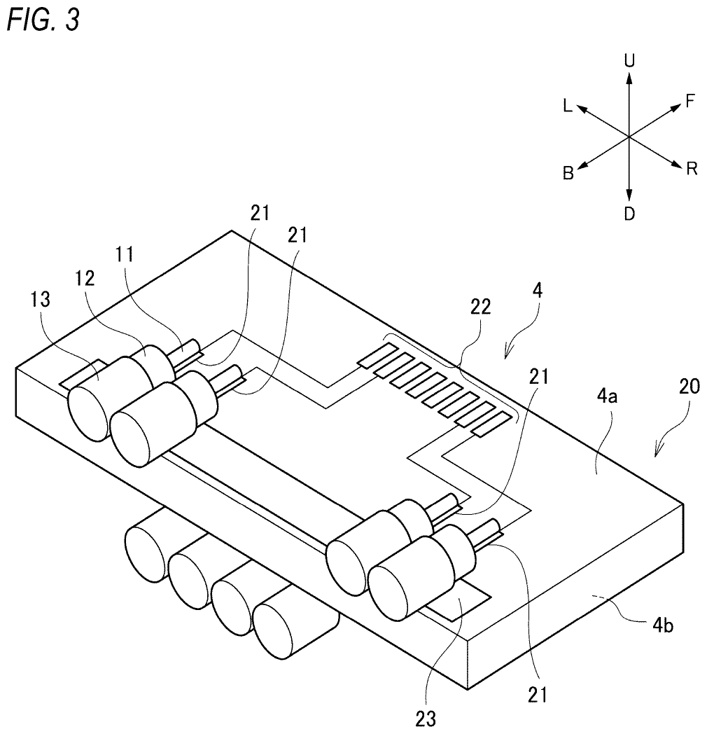

As shown in FIG. 1, the connector 3 includes a circuit board 4, a boot 5 covering the circuit board 4, and a connection portion 7. The circuit board 4 includes a wiring portion 20 on which a circuit pattern is printed on a front surface facing an upward direction (U direction) and a back surface facing a downward direction (D direction) (see FIG. 3). A strain relief 6 for protecting a connection part between the cable 2 and the connector 3 is provided at one end of the boot 5. In the following description, for convenience of description, a direction from a central portion of the connector 3 toward the connection portion 7 is referred to as the front direction, and a direction from the central portion of the connector 3 toward the strain relief 6 that is opposite to the front direction is referred to as the rear direction. The connection portion 7 protrudes forward from the boot 5. When the connector-attached cable 1 is connected to electronic devices, a device-side wiring portion is electrically connected to wiring in the electronic device.

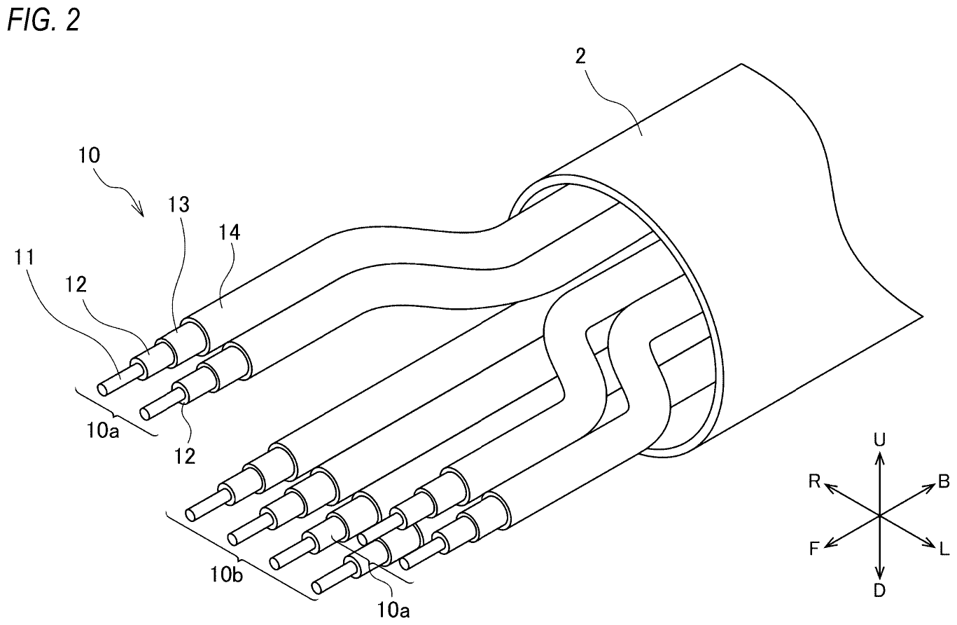

Next, the cable 2 according to the present embodiment will be described with reference to FIG. 2. FIG. 2 is an enlarged view of a front end portion of the cable 2 shown in FIG. 1.

As shown in FIG. 2, the cable 2 in the present embodiment includes a plurality of coaxial wires 10 as electronic wires. The electronic wire used for the cable 2 of the present disclosure is not limited to the coaxial wire, and for example, an insulated wire including a conductor and an insulating layer covering the conductor may be used. The coaxial wire 10 includes a center conductor 11, an inner insulating layer 12 covering the center conductor 11, an outer conductor 13 covering the inner insulating layer 12, and a jacket 14 covering the outer conductor 13. In the present embodiment, the jacket 14 is also an insulating layer covering the outer conductor 13. The coaxial wire 10 is step-stripped at an end portion thereof so as to expose the center conductor 11, the inner insulating layer 12, and the outer conductor 13 in this order.

The center conductor 11 is a single wire made of a conductive metal such as a copper alloy or a twisted wire formed by twisting a plurality of thin wires. The inner insulating layer 12 is made of an insulating resin, and electrically insulates the center conductor 11 from the surroundings while protecting the center conductor 11. The outer conductor 13 is implemented by a metal braid, metal plating, or the like, prevents leakage of noise, and prevents noise from being superimposed on a signal propagating through the center conductor 11. The jacket 14 is an insulating layer made of an insulating resin, and prevents damage to the outer conductor 13 while electrically insulating the outer conductor 13 from the outside.

The plurality of coaxial wires 10 can be arranged in pairs. The coaxial wires 10 can be divided into a first group 10a connected to the front surface of the circuit board 4 and a second group 10b connected to the back surface of the circuit board 4. A method of dividing the coaxial wires 10 is not limited to the example shown in FIG. 2.

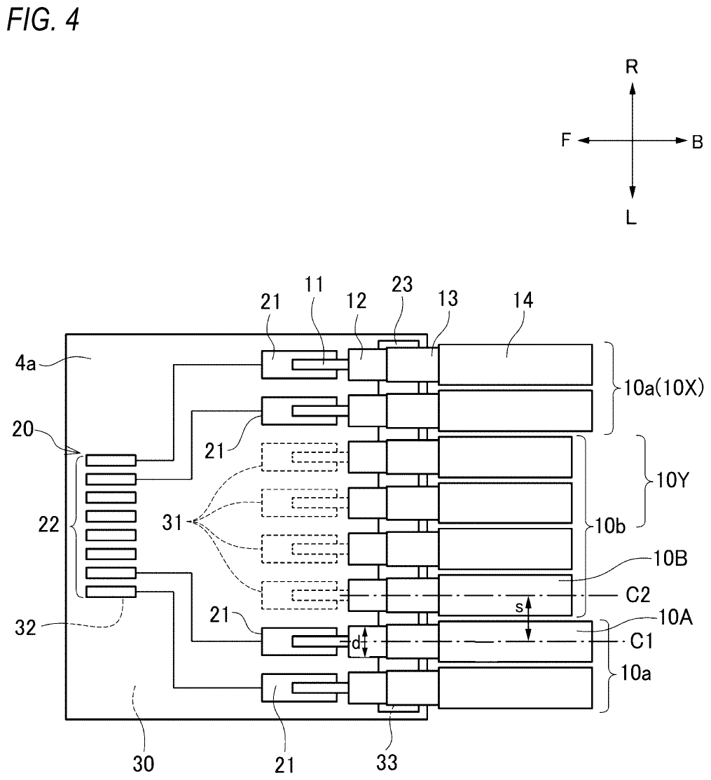

Next, a connection form between the coaxial wires 10 and the circuit board 4 in the present embodiment will be described with reference to FIGS. 3 and 4.

FIG. 3 is a schematic perspective view showing an example of the connection form between the circuit board 4 and the coaxial wires 10 according to the present disclosure. As shown in FIG. 3, the circuit board 4 has a first surface 4a and a second surface 4b on a back side of the first surface 4a. The first surface 4a includes the wiring portion 20. FIG. 4 is a projection view of the coaxial wires 10 and the circuit board 4 seen from above the first surface 4a of the circuit board 4, and is also a perspective view of the coaxial wires 10 under the second surface 4b with broken lines as seen through the circuit board 4. The wiring portion 20 on the first surface 4a includes wire pads 21, connector pads 22, and a ground pad 23. Each of the connector pads 22 is provided at a foremost position on the circuit board 4 in order to enable wiring in a space inside the connection portion 7 shown in FIG. 1. Each of the ground pads 23 is provided at a rearmost position on the circuit board 4. The outer conductor 13 of the coaxial wire 10 is connected to the ground pad 23. The wire pad 21 is provided on the circuit board 4 and closer to a center of the circuit board than the ground pad 23. The wire pads 21 and the connector pads 22 are electrically connected, respectively. Although not shown, the second surface 4b includes a wiring portion 30 similarly to the first surface 4a, and the wiring portion 30 includes wire pads 31, connector pads 32, and a ground pad 33. The wiring portion 20 and the wiring portion 30 may not have the same wiring pattern. Positions of the wire pads 31 on the second surface 4b in the right direction or the left direction do not overlap those of the wire pads 21 on the first surface 4a in FIG. 4. The connector pads 22 on the first surface 4a and the connector pads 32 on the second surface 4b are electrically connected to an electrical device (not shown) connected to the connector 3.

An end portion of the coaxial wire 10 in the F direction is step-stripped and connected to the circuit board 4. The center conductor 11 of the coaxial wire 10 is connected, by soldering or the like, to the wire pad 21 on the wiring portion 20 or the wire pad 31 on the wiring portion 30 provided on the circuit board 4. The outer conductor 13 of the coaxial wire 10 is connected, by soldering or the like, to the ground pad 23 on the wiring portion 20 or the ground pad 33 on the wiring portion 30 provided on the circuit board 4.

The first group 10a of the coaxial wires 10 is connected to the first surface 4a of the circuit board 4, and the second group 10b of the coaxial wires 10 is connected to the second surface 4b of the circuit board 4. The center conductors 11 of the coaxial wires 10 in the first group 10a are paired and connected to the wire pads 21 on the first surface 4a. The center conductors 11 of the coaxial wires 10 in the second group 10b are paired and connected to the wire pads 31 on the second surface 4b.

Further, in the connector-attached cable 1 according to the present embodiment, in a projection view of the electronic wires seen from a direction orthogonal to the first surface 4a or the second surface 4b, an overlapping width between an electronic wire pair in the first group 10a connected to the first surface 4a and an electronic wire pair in the second group 10b connected to the second surface 4b among electronic wire pairs connected to different surfaces and closest to each other in the projection view is smaller than a diameter of the electronic wire.

For example, as shown in FIG. 4, an electronic wire pair 10X in the first group 10a is connected to the first surface 4a, and an electronic wire pair 10Y in the second group 10b is connected to the second surface 4b. The electronic wire pair 10X and the electronic wire pair 10Y are electronic wire pairs closest to each other in the projection view shown in FIG. 4, and the electronic wire pair 10X and the electronic wire pair 10Y are arranged such that an overlapping width therebetween is smaller than a diameter of the coaxial wire 10.

In the connector-attached cable 1 according to the present embodiment, when viewed in FIG. 4, when a diameter of the inner insulating layer 12 of the coaxial wire 10 is set as d and a distance between center lines of the electronic wires which are two electronic wires adjacent to each other and connected to different surfaces of the circuit board in FIG. 4 is set as S, a relationship in the following Formula (1) is satisfied. In other words, in the connector-attached cable 1 according to the present embodiment, when a distance between a center line of the coaxial wire 10 on one side (the right side or the left side) in the electronic wire pairs in the first group 10a and a center line of the coaxial wire 10 on the other side (the left side or the right side) in the electronic wire pairs in the second group 10b is set as S and a diameter of the inner insulating layer of the coaxial wire 10 is set as d, the relationship in the following Formula (1) is satisfied.

$$S \geq 0.35 d \qquad ( 1 )$$

In order to satisfy the above relational formula, the plurality of coaxial wires 10 of the connector-attached cable 1 according to the present disclosure are arranged in a manner of not overlapping or having a small overlapping amount when viewed from above at a portion connected to the circuit board 4 and a portion protruding slightly backward from the circuit board.

As shown in FIG. 4, in the present embodiment, a coaxial wire 10A is connected to the first surface 4a of the circuit board 4, and a coaxial wire 10B is connected to the second surface 4b of the circuit board 4. The coaxial wire 10A and the coaxial wire 10B are adjacent electronic wires when viewed from above, and the diameter d of the inner insulating layer 12 is 0.2 mm. On the other hand, the distance S between a center line C1 of the coaxial wire 10A and a center line C2 of the coaxial wire 10B is 0.3 mm. Therefore, in this example, S≥d, and the relationship in the above Formula (1) is satisfied. For example, when the coaxial wire 10 in which the diameter d of the inner insulating layer 12 is 0.2 mm is connected, the distance S between the center line C1 and the center line C2 is allowed to be 0.07 mm or more.

In the connector-attached cable 1 according to the present disclosure, it is desirable to satisfy the following Formula (2) in order to further reduce the overlapping amount between the coaxial wires 10 in the above connection form.

$$S \geq 0.85 d \qquad ( 2 )$$

For example, when the coaxial wire 10 in which the diameter d of the insulating layer is 0.2 mm is connected, the distance S between the center line C1 and the center line C2 is preferably 0.17 mm or more.

Generally, in a connector-attached cable, when connecting an electronic wire to a circuit board, a preliminary processing step of processing the electronic wire with a laser or the like in order to expose a center conductor and an outer conductor of the electronic wire before the connection to the circuit board is required. For example, the electronic wires are arranged in parallel, a laser beam is applied to the electronic wires from an upper surface or a lower surface of a parallel surface, and a laser irradiation point is moved in a parallel direction of the electronic wires. The jackets, the outer conductors, and the insulating layers of the electronic wires arranged in parallel are cleaved. At this time, when the electronic wires connected to the front surface of the circuit board and the electronic wires connected to the back surface of the circuit board are arranged in a state of overlapping each other in a view seen from above the parallel surface, it is difficult to cleave desired jackets or the like by irradiating all the electronic wires with a laser in one laser processing step. Therefore, the laser irradiation for the preliminary processing needs to be performed a plurality of times, and the preliminary processing step takes time.

Therefore, the inventors have found that the number of times of laser processing can be reduced by arranging the electronic wires to reduce a portion where the electronic wires overlap each other in a view of the connector-attached cable seen from above the first surface or the second surface.

The preliminary processing of the electronic wire using the laser can be performed when, regarding each of two electronic wires which are adjacent electronic wires and are connected to different surfaces of the circuit board, at least 35% or more of a width of a cleaved portion of the electronic wire can be visually recognized (in other words, an overlapping portion between the electronic wires at the cleaved portion is 65% or less of the width of the portion) in a view seen from a direction perpendicular to the front surface of the circuit board, and more preferably 85% or more of the width can be visually recognized. For example, when cleaving an insulating layer of an insulated wire, the preliminary processing using the laser can be performed when the overlapping portion between the electronic wires is 65% or less of a width of the insulating layer. Further, when cleaving a jacket of a coaxial wire, the preliminary processing using the laser can be performed when the overlapping portion between the electronic wires is 65% or less of a width of the jacket.

In the connector-attached cable 1 of the present disclosure, by arranging the electronic wires to satisfy the above Formula (1) or (2), it is possible to irradiate portions of all the electronic wires, which need to be preliminarily processed, with the laser without changing the arrangement of the electronic wires. In addition, since a portion where the electronic wires overlap each other is small, the number of times of the laser irradiation can be reduced, and the preliminary processing before connection of the electronic wires can be simplified.

According to the above configuration, a connector-attached cable capable of simplifying a step of connecting the electronic wires to the circuit board can be provided.

Further, in the connector-attached cable 1 according to the present disclosure, when a coaxial wire including a center conductor, an insulating layer, an outer conductor, and a jacket is adopted as the electronic wire, the above effect is more remarkable. When the above coaxial wire is connected to the circuit board, the coaxial wire needs to be step-stripped such that the center conductor, the insulating layer, and the outer conductor are exposed in this order. Therefore, the preliminary processing before the coaxial wire is connected to the circuit board tends to be more complicated. In the connector-attached cable 1 according to the present disclosure, since a step of connecting the electronic wire to the circuit board 4 can be simplified, when the coaxial wire 10 which requires a plurality of times of processing before being connected to the circuit board is adopted, the preliminary processing step can be simplified particularly.

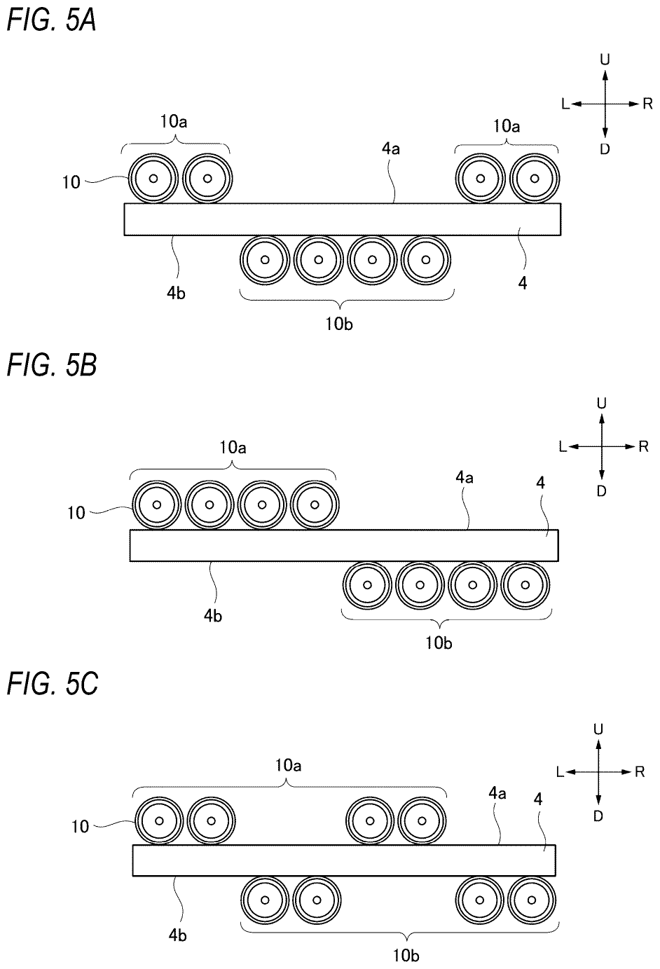

In the connector-attached cable 1 according to the present disclosure, it is preferable that the electronic wires are connected to each of the first surface 4a and the second surface 4b in even pairs. FIG. 5A is a cross-sectional view of the electronic wires and the circuit board 4 orthogonal to an axial direction, showing a connection form of the connector-attached cable 1 according to the above embodiment. Each of FIGS. 5B and 5C is a cross-sectional view of the electronic wires and the circuit board 4 orthogonal to the axial direction, showing another example of the connection form of the connector-attached cable 1 according to the present disclosure. In the connector-attached cable 1 according to the present disclosure, when the electronic wires are connected in pairs and connected to each of the first surface 4a and the second surface 4b in even pairs, the electronic wires may be arranged, for example, as shown in FIGS. 5A to 5C.

In an arrangement of the coaxial wires 10 shown in FIG. 5A, the coaxial wires 10 in the first group 10a are connected to both end portions in a width direction of the circuit board 4 in an arrangement direction of the coaxial wires 10 on the first surface 4a of the circuit board 4. The coaxial wires 10 in the second group 10b are connected to a center portion of the circuit board 4 in the arrangement direction of the coaxial wires 10 on the second surface 4b of the circuit board 4.

In an arrangement of the coaxial wires 10 shown in FIG. 5B, the coaxial wires 10 in the first group 10a are connected to a left portion which is one side in the width direction of the circuit board 4 in the arrangement direction of the coaxial wires 10 on the first surface 4a of the circuit board 4. The coaxial wires 10 in the second group 10b are connected to a right portion, which is different from the end portion to which the coaxial wires 10 in the first group 10a are connected, in the arrangement direction of the coaxial wires 10 on the second surface 4b of the circuit board 4.

In an arrangement of the coaxial wires 10 shown in FIG. 5C, the coaxial wires 10 in the first group 10a and the coaxial wires 10 in the second group 10b are alternately connected with the circuit board 4 interposed therebetween.

The arrangements shown in FIGS. 5A to 5C all satisfy S≥d in relation to the above d and S, and satisfy the relational Formulas (1) and (2).

Although not shown in FIGS. 2 to 4 for the sake of visibility, the cable 2 may further include electronic wires other than the coaxial wires 10. Further, the electronic wires other than the coaxial wires 10 may be connected to the circuit board 4.

Although the embodiment of the present disclosure has been described above, it goes without saying that the technical scope of the present disclosure should not be interpreted to be limited by the description of the present embodiment. The present embodiment is merely an example, and it is understood by those skilled in the art that various modifications can be made to the present embodiment within the scope of the invention described in the claims. The technical scope of the present disclosure should be defined based on the scope of the invention described in the claims and the scope of equivalents thereof.

1. A connector-attached cable comprising:
a cable including a plurality of electronic wires; and
a connector connected to the cable, wherein
the connector includes a circuit board,
each of the electronic wires includes a conductor and an insulating layer covering the conductor,
at least a part of the plurality of electronic wires is connected to the circuit board with two adjacent electronic wires as a pair,
a part of the plurality of conductors is connected to a first surface of the circuit board, and the other part of the plurality of conductors is connected to a second surface on a back side of the first surface,
in a projection view of the electronic wires seen from a direction orthogonal to the first surface or the second surface, an overlapping width between an electronic wire pair in a first group connected to the first surface and an electronic wire pair in a second group connected to the second surface among electronic wire pairs which are connected to different surfaces and closest to each other in the projection view is smaller than a diameter of the electronic wire, and
when a distance between center lines of two of the electronic wires which are connected to different surfaces and overlap each other in the projection view is set as S, and a diameter of the insulating layer of the electronic wire is set as d, a relationship of the following Formula (1) is satisfied,
$$S \geq 0.35 d . \qquad ( 1 )$$

2. The connector-attached cable according to claim 1, wherein
the electronic wire is a coaxial wire including the conductor, an inner insulating layer, an outer conductor covering the inner insulating layer, and the insulating layer covering the outer conductor.

3. The connector-attached cable according to claim 1, wherein
in the projection view, the diameter d of the insulating layer and the distance S satisfy a relationship of the following Formula (2),
$$S \geq 0.85 d . \qquad ( 2 )$$

4. The connector-attached cable according to claim 1, wherein
the electronic wires are connected to each of the first surface and the second surface in even pairs.
